(19) United States
(12) Patent Application Publication
(10) Pub. No.: US 2023/0422410 A1
(43) Pub. Date: Dec. 28, 2023

(54) SYSTEM AND METHOD FOR FABRICATING EXTENDED LENGTH FLEXIBLE CIRCUITS

(71) Applicant: All Flex Solutions, Inc., Northfield, MN (US)

(72) Inventor: Jason David Hoium, Richfield, MN (US)

(21) Appl. No.: 18/342,191

(22) Filed: Jun. 27, 2023

Related U.S. Application Data
(60) Provisional application No. 63/367,181, filed on Jun. 28, 2022.

(51) Int. Cl. H05K 3/46

(52) U.S. Cl. CPC H05K 3/4635; H05K 2203/166; H05K 2203/068

(57) ABSTRACT

A method of manufacturing a flexible circuit comprised of conducting and insulating layers in an extended length format using multi-point registration to benefit subsequent processing and utilizing one pass printing for up to 110 inches in conjunction with a large format press or alternatively a combination of step press cycles.

### RELATED APPLICATION

This application claims priority from U.S. Provisional Application No. 63/367,181 filed on Jun. 28, 2022. The content of this application is incorporated herein by reference in it its entirely.

### FIELD OF THE DISCLOSURE

A system and method for manufacturing a flexible circuit comprised of conducting and insulating layers in an extended length format using multi-point registration to benefit subsequent processing and utilizing one pass printing for up to and potentially more than 110 inches in conjunction with a large format press or alternatively a combination of step press cycles.

### BACKGROUND

Flexible circuits, also known as flexible printed circuit boards (PCBs), are an essential component of modern electronic devices. They are made of thin and flexible engineered polymer materials, which allows them to bend and conform to any shape or contour. The importance of flexible circuits lies in their ability to provide a robust and efficient solution to many design challenges that traditional rigid PCBs cannot solve.

One of the most significant advantages of flexible circuits is their ability to save space. With the trend towards miniaturization of electronic devices, space is at a premium. Flexible circuits can be designed to fit into small spaces, allowing the design of smaller, more compact devices. Additionally, flexible circuits can be designed to be folded or stacked, which further increases space savings. This makes them ideal for use in smartphones, wearable technology, and other small electronic devices.

Another important advantage of flexible circuits is their ability to improve reliability. Flexible circuits are more resistant to vibration, shock, and temperature changes than rigid PCBs. This means that they are less likely to fail due to mechanical stress, and they can be used in harsh environments where traditional rigid PCBs would fail. This makes them ideal for use in aerospace, military, and industrial applications, where reliability is essential.

Flexible circuits are also more cost-effective than rigid PCBs. They require less material and fewer processing steps, which reduces manufacturing costs. Additionally, flexible circuits can be produced in high volumes using automated manufacturing processes, which further reduces costs. This makes them an attractive option for manufacturers looking to reduce production costs without compromising quality.

Finally, flexible circuits allow for greater design flexibility. With rigid PCBs, designers are limited to a flat, two-dimensional layout. With flexible circuits, however, designers can create three-dimensional layouts that conform to the shape of the device. This opens new possibilities for innovative designs that were previously impossible with traditional rigid PCBs.

In conclusion, the importance of flexible circuits lies in their ability to provide a robust and efficient solution to many design challenges that traditional rigid PCBs cannot solve. They offer space savings, improved reliability, cost-effectiveness, and greater design flexibility, making them an essential component of modern electronic devices. As the demand for smaller, more reliable, and more innovative electronic devices continues to grow, the importance of flexible circuits will only increase.

Historically, flexible circuits are a high-growth technology in electrical interconnectivity and are set to deliver improved performance against the demands of many twenty-first century products. The compact nature of flexible circuits and the high electrical-connection density that they can achieve offer considerable weight, space, and cost savings over the use of traditional rigid printed circuit boards, wire, and wire harnesses.

As noted above, flexible printed circuits are found in everything from automobiles, medical equipment to sophisticated military and avionics systems. High-profile applications of flexible circuits are many. Flexible-circuit technology has a well-established history that goes back nearly one hundred years. Early patent activity highlights the fact that concepts for flexible-circuit materials and designs, which have only come into commercial use within the last few decades, were speculated upon by inventors in the early twentieth century.

The heart and soul of Flexible Printed Circuits (FPCs) are the flexible films and thin layers of conductive circuit traces. These typically constitute the base flexible-circuit laminate, which can be utilized to interconnect electronics as a reliable wiring replacement or can have electronic components directly attached to it via soldering or conductive adhesive, to form a finished, pliable circuit board. Any assessment of the technology of flexible circuits quickly identifies a whole range of benefits that complement and surpass the capabilities of rigid printed circuit boards (PCBs). For many, the technology of flexible circuits and their wide applications may be new, and the view of flexible circuits may be restricted to that of simple point-to-point connections, as a replacement for traditional electrical wire for example.

This is currently far from the case and the promise of flexible circuitry is highly significant. With new applications and new materials continually being designed and developed, the technology promises to revolutionize many aspects of electronic circuit design. One of the primary challenges with the fabrication of extended length flexible circuits, i.e., those over 36 inches, is ensuring the continuity of the traces along the entire span of the circuit. Early efforts to fabricate extended length flexible circuits yielded very high failure rates due to misalignment of the conductors along the entire length of the circuit. This misalignment of the conductors is brought about by environmental influences such as changes in temperature and fabrication related influences that cause movement of the circuit that adversely impacts the ability of the fabricator to control the trace alignment.

### SUMMARY

Flexible printed circuits, also known as flex circuits, are sometimes regarded as a printed circuit board (PCB) that can bend, when really there are significant differences between PCBs and flex circuits when it comes to design, fabrication and functionality. The word “printed” is somewhat of a misnomer as many of the manufacturing processes today use photo imaging or laser imaging as the pattern definition method rather than printing.

A flexible printed circuit consists of a metallic layer of traces, usually copper, bonded to a dielectric layer, usually polyimide. Thickness of the metal layer can, for example, be very thin (<0.0001 inch) to very thick (>0.010 inch) and the dielectric thickness can vary from 0.0005 inches to 0.010 inches. Often an adhesive is used to bond the metal to the substrate, but other types of bonding such as vapor deposition can be used to attach the metal.

Because copper tends to readily oxidize, the exposed surfaces are often covered with a protective layer; gold or solder are the two most common materials because of their conductivity and environmental durability. For non-contact areas a dielectric material is used to protect the circuitry from oxidation or electrical shorting.

Disclosed herein is a method to utilize multi-dimensional imaging technology to record with a camera multiple reference points (e.g., tooling holes) along both longitudinally extending sides of a flexible laminate and then use software to digitize the location of each reference point within a computer centric coordinate system. This digitization of the location of the reference points occurs along longitudinally extending discrete sections of the extended length flexible laminate and includes multiple reference points for each designated section. The system software precisely digitally stitches together these discrete sections thereby allowing subsequent fabrication processes, upon the flexible laminate, to utilize the positional data of all reference points and to maximize the precision of those subsequent processes.

The use of registration points has been shown to create continuous laminate structures unencumbered by multiple exposure stitching, at the boundaries between the adjacent sections, and the errors that can come from it. A multi-dimensional vision system captures the reference points, e.g., tooling holes and all the surficial data that lies between the various tooling holes for each section. This initial reference data (tooling hole locations) is then compared with subsequent scans of the flexible circuit to determine if any shifting in location along a coordinate system has occurred at any of the reference features.

As noted above, this multi-reference feature methodology also translates to subsequent processes allowing registration to take place at the same locations down the entirety of the length of a panel and have the transformation hinge points (section demarcations) remain constant. This results in an ideal transformation of all process data, allowing the fabrication equipment to accommodate any distortions inherited by the flexible laminates.

Subsequent processes may also utilize the same reference locations to allow precise additional processing and alignment to previous processes. This achieves the high precision tolerance required for fine line structures, e.g., copper traces, in combination with extended length circuits. These subsequent processes utilize the same reference locations as the direct dry film image which created the pattern for the circuit structures. This allows the subsequent processes to have alignment continuity throughout the entire sequence of processing steps.

It is an object of the disclosed method to prevent misalignment of longitudinally extending conductor traces by utilizing digital imaging technology to acquire multiple reference points along the entirety of an extended length circuit and perform a digital transformation of each section, precisely digitally stitching them together and subsequently performing the entire exposure in one operation.

Various objects, features, aspects, and advantages of the disclosed subject matter will become more apparent from the following detailed description of preferred embodiments. The contents of this summary section are provided only as a simplified introduction to the disclosure and are not intended to be used to limit the scope of the appended claims.

The contents of this summary section are provided only as a simplified introduction to the disclosure and are not intended to be used to limit the scope of the appended claims.

### BRIEF DESCRIPTION OF THE DRAWINGS

FIG. 1 illustrates the registration features on an embodiment of a substrate laminate panel in original form;

FIG. 2 illustrates an embodiment of a substrate laminate panel with reference features and demarcation lines separating the panel into multiple sections at the reference features;

FIG. 3 illustrates a shifting of substrate laminate panel registration features following a fabrication step;

FIG. 4 illustrates the use of a multi-dimensional vision system to obtain reference feature information and the implementation of a measurement algorithm to assess shifting in the reference features;

FIG. 5 illustrates an embodiment of a substrate laminate panel with an electrical conductor;

FIG. 6 illustrates a process flow diagram for the method of fabrication of the extended length flexible circuits;

FIG. 6A illustrates a continuation of the process flow diagram of FIG. 6;

FIG. 7 illustrates an embodiment of a substrate laminate panel with a demarcation line and two sections; and

FIG. 8 illustrates the delivery of a beam of electromagnetic energy on to a photo-sensitive film.

### DETAILED DESCRIPTION

Flexible laminates are known to have dimensional variation, and extended length flexible circuits which are fabricated from flexible laminates can encounter movement and distortion during the fabrication process causing fine features and tight tolerances to be very difficult to achieve. The use of digital imaging methodologies and systems to create patterned features on dry film in standard size formats and subsequently step and repeat sequences has resulted in stitching errors due to these material changes and errors in reference point systems.

These stitching errors can create undesirable misalignment of the copper trace conductors that extend between digitized sections of the long flexible laminate. It has also been shown that standard size format static press systems are poorly suited to the lamination of extended length circuits, i.e., those over 24 inches in length.

Disclosed herein are a system 10 and method that utilize digital imaging technology to identify multiple reference points along the entirety (entire perimeter) of an extended length flexible laminate 12 and perform a digital transformation of each of multiple sections, precisely digitally stitching the sections together at demarcation lines L1-LX spanning between the laterally opposed edges. Disclosed herein is a system and method for use of multiple reference features 14 to create a seamless digital map 16 of multiple adjacent sections 18 separated by demarcation lines L1-LX, passing through the center of opposed reference features that are unencumbered by multiple exposure stitching and the errors that can arise from it.

Multiple exposure stitching errors arise when a point, or a digitally imposed line, on the flexible laminate no longer resides at the location originally identified by the CAD software data specifying the physical attributes of the flexible laminate 12. This multi-point reference methodology is also translated to subsequent fabrication processes allowing multi-dimensional digital images to be taken at the same reference points along the entirety of the length of a panel and have the transformation demarcation lines (also known as hinge lines) remain constant. This results in an ideal fluid transformation of all process data, matching any distortions inherited by the flexible laminates 12.

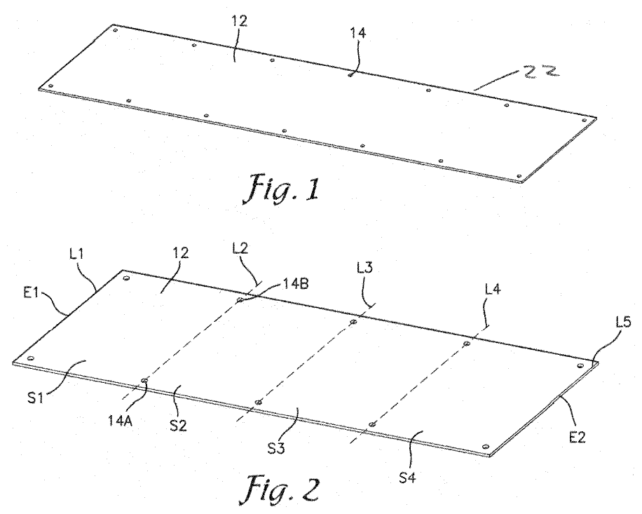

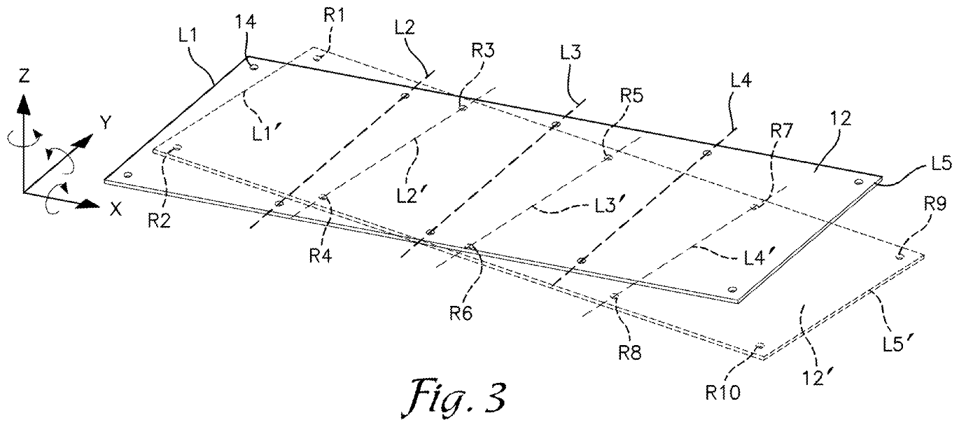

FIG. 1 illustrates a typical flexible laminate 12 with multiple reference features 14, such as holes introduced into the laminate 12, adjacent the outer perimeter 22 of the longitudinally extending flexible laminate 12. While a plurality of reference features 14 are utilized for this simplified exemplary illustration, it is contemplated that a greater number, or possibly even a lesser number of reference features 14 may be digitized. During the digitization process of the flexible laminate 12, FIG. 2 illustrates a depiction of the same flexible laminate digitally broken into four sections S1-S4 by three demarcation lines L1-L5. Demarcation lines L1 and L5 are identified in this figure as the first and second longitudinally opposed edges E1 and E2. The four sections S1-S4 in this digital embodiment of the exemplary flexible laminate 12 each extend longitudinally a predefined distance, e.g., inches though different section lengths are contemplated by this disclosure. FIG. 2 illustrates digitally imposed section lines L1-L5 spanning laterally between sections S1-S4.

The digital demarcation lines L2-L4 as shown in FIG. 2, pass through the center of the reference features 14A and 14B. It is critical that the digital demarcation lines for this system and method pass through either the center of the reference features, for example 14A, 14B as illustrated at FIG. 2, or are identified as the longitudinally opposed edges E1, E2. Because of the precision with which the reference features 14, 14A, 14B are positioned within the flexible laminate, it is the passing of the demarcation lines L1-LX through these digitally captured features that permits the finely tuned “digital stitching” together of the multiple sections of the flexible laminate 12.

A greater number as well as a fewer number of sections S1-SX (with X serving as a variable) are also contemplated by this disclosure with the number of sections generally dependent upon the customer specified overall length of the flexible laminate 12. Section longitudinal span is a parameter that can readily be adjusted within the controlling software to align with the specifications for fabrication of the flexible circuit. As previously noted, the original reference features 14 coincide with for example, tooling holes, that are placed within the laminate panel 12 based upon the laminate panel design specifications that are loaded into the software database that then controls the placement of the reference features (i.e., tooling holes).

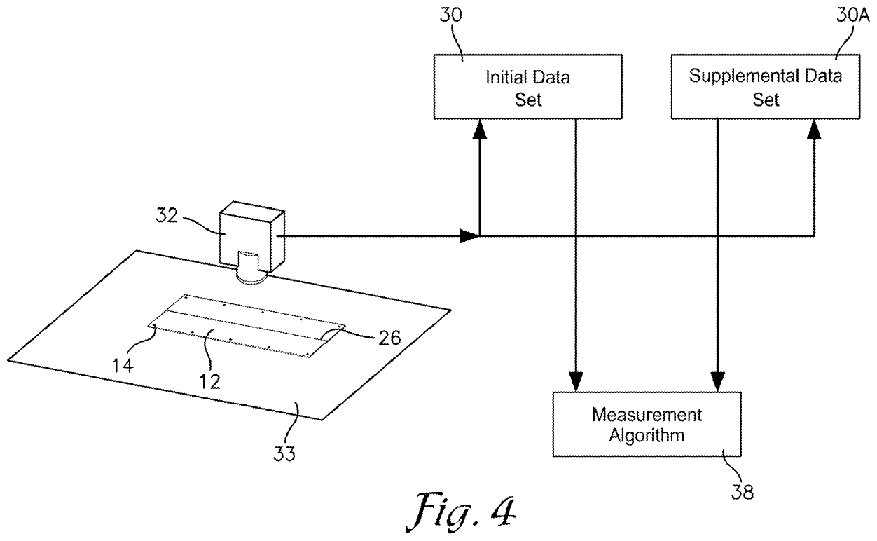

FIG. 3 illustrates an overlay of the flexible laminate 12 of FIG. 2 in dashed lines of a generalized displacement of the flexible laminate 12 following a typical fabrication process (step) such as chemical washing of the flexible laminate 12. The original orientation of the flexible laminate 12 is shown in solid lines while the slightly varied orientation of the flexible laminate 12′ is shown in dashed lines. During a typical laminate panel fabrication process it is not uncommon for a one or more of the previously captured reference features 14 to shift in some manner to a new positions R1-R10. The shifting of reference features in FIG. 3 is exaggerated to highlight the shifting that can occur during the fabrication steps.

These reference feature displacements are induced through chemical, physical or environmental influences (e.g., temperature changes or due to vibration of the associated fabrication equipment, etc.) and from fabrication processes that alter ever so slightly the original reference feature 14 locations. The subsequently captured digital data reveals the change in position along for example, a cartesian coordinate system (X, Y, Z) or a polar coordinate system (R, α). It is also contemplated that rotation of each of the reference features 14 following a fabrication step are also optionally calculated. Rotation information may also be utilized in the stitching together of the various segments S1-SX along the demarcation lines L1-LX. FIG. 3 reveals updated demarcation lines L1′-L5′ that resulted from shifting of the original lines L1-L5 following the fabrication steps.

As illustrated at FIG. 4, the reference feature 14 visual data 30 is acquired with a multi-dimensional machine vision system 32. The flexible laminate panel 12 is securely held in a fully flat position with, for example, a vacuum table 33. A multi-dimensional machine vision system 32 is capable of, for example, two-dimensional (2D) vision that uses one or more digital cameras to capture the image of an object. An exemplary provider of 2D vision systems is Cognex® Corporation located in Natick, Massachusetts. With 2D machine vision, a two-dimensional map (X, Y) of reflected intensity is captured and processed. A two-dimensional data image, however, does not provide any elevation information. Should elevation data be required in a variant of the system as disclosed herein, a 3D machine vision system may alternatively be employed. 2D machine vision systems are extensively used throughout the industrial automation industry in a wide range of tasks, including dimension checking. Positioning and measuring are tasks that 2D machine vision systems are highly capable of addressing.

Once the multi-dimensional machine vision system 32 has acquired the dataset 30 for the original flexible laminate panel 12 a second scan of the post-fabrication-step flexible laminate panel 12′ (as best seen in FIG. 3) by the machine vision system creates a second data set 30 following the initial fabrication step. As illustrated at FIG. 4, a measurement algorithm 38 operable as a feature of the multi-dimensional vision system then executes upon the visually acquired data sets 30, 30A to determine the two-dimensional displacement, caused by the fabrication step, of the reference points R1-R10, relative to the original locations of the reference points.

With multi-dimensional machine vision, robust dimensional data is available from the captured images of the shifted reference features R1-R10 upon the flexible laminate 12′. It is well understood in the art area of machine vision how to determine the shifting (direction and magnitude) of reference features from the original visually acquired reference features 14 following one or more fabrication steps. Dimensional inspection with image processing produces not only pass/fail judgments, but also numerical data for the specific dimensions of various components. Another advantage is that manufacturers can measure components and save all data acquired by the machine vision system for statistical process control.

The machine vision algorithm 38 calculates the displacement of each of the reference points from their original location as determined by the original dataset 30 relative to R1-R10 respectively and provides the adjustments needed for subsequent fabrication processes to maintain the highly precise alignment of each section S1-S4 with the adjacent sections—in effect stitching the sections together. For example, and as illustrated at FIG. 3, reference point R4 following a fabrication step has shifted approximately 0.08 inches along an X-axis and 0.07 inches along a Y-axis or a straight-line shift of the reference point of 0.106 inches at an angle of about 41 degrees. Failing to accommodate for this positional shift of 0.106 inches at an angle of about 41 degrees for reference point R4 would likely result in a finished fabricated flexible circuit that is inoperable due to interruption of the continuity of one or more electrical conductors 26 that spans the entire length of the flexible laminate panel.

As previously noted, there exists a requirement to maintain continuity of trace lines 26 as narrow as 0.002 inches along the entire longitudinal expanse of the flexible laminate 12 without deviation. Maintaining very tight tolerances to achieve this conductor trace 26 continuity is vital to the functionality of the fully fabricated flexible laminate 12. The system and method 10 disclosed herein can accommodate these reference point R1-R10 displacements along the entire longitudinal expanse of the flexible laminate 12 and specifically between adjacent sections S1-S4 at the digitally imposed demarcation (stitch) lines L1-L5. As noted above, maintaining positional knowledge of the entire span of the digital demarcation (stitch) lines L1-LX that extend between the center of the reference features R1-RX that are disposed laterally opposite one another along the entire longitudinal span is central to the system and method 10 disclosed herein.

The multi-dimension machine vision system 32 scans the flexible laminate 12 following subsequent fabrication processes (steps) utilizing the same initially assigned reference features 14 and compares those initial reference features with the location of each reference feature R1-R10 following the subsequent fabrication process as illustrated at FIG. 3. The subsequent adjustment of the next fabrication step to precisely accommodate the positional shift of each reference feature R1-R10, as determined by the machine vision software, facilitates the achievement of the precise tolerances required for fine line structures, e.g., 0.002-inch-wide conductor traces 26, as the conductor traces longitudinally traverse the flexible laminate 12.

Subsequent fabrication processes (steps) utilize the same transformation technique as disclosed above. This allows the subsequent processes to maintain alignment continuity throughout the entire fabrication process. This method can be applied to all construction types, single conducting layer, double sided with or without electrically connecting conductive traces, and multilayer construction.

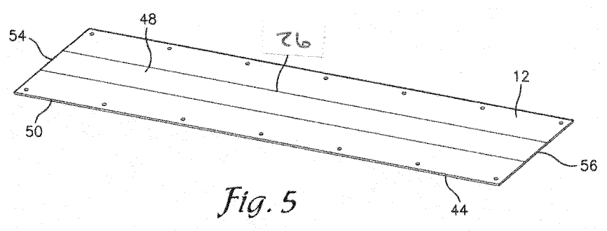

As illustrated at FIG. 5, there are several basic material elements that constitute a flexible circuit 12: a dielectric substrate film (base material) 44, electrical conductors (circuit traces) 26, a protective finish (cover lay or cover coat) 48, and, not least, adhesives 50 to bond the various materials to one another. Together the above materials form a basic flexible circuit laminate 12 suitable for use as a simple wiring assembly, or capable after further processing of forming a compliant final circuit assembly. Within a typical flexible-circuit construction the dielectric film 44 forms the base layer, with adhesives 50 used to bond the conductors 26 to the dielectric 44 and, in multilayer flexible circuits, to bond the individual layers together.

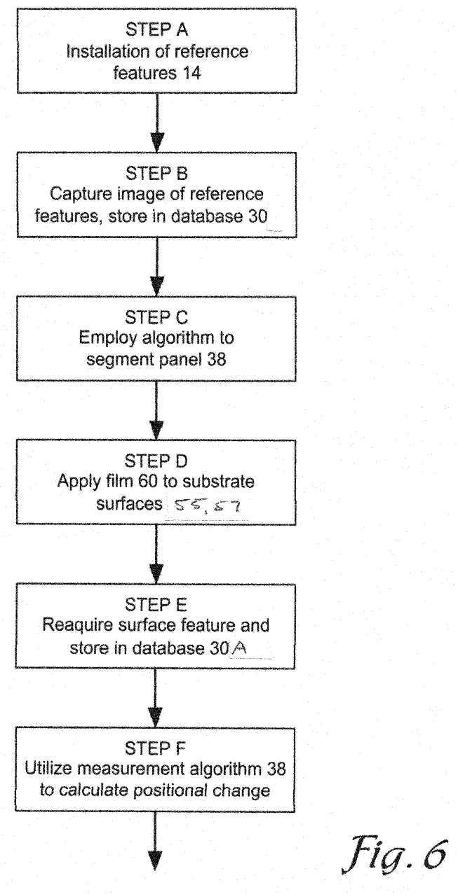

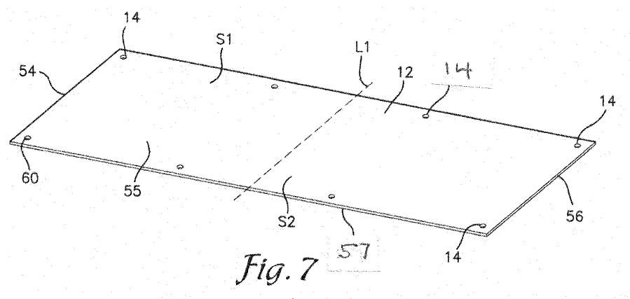

Disclosed herein and as set forth in the process flow diagram of FIGS. 6 and 6A and as illustrated at FIG. 7 is a typical, but by no means exclusive, method for fabricating an extended length flexible circuit 12 with longitudinally opposed first and second ends 54, 56. Step A in the method requires the installation of reference features 14 such as tooling holes consistent with initial data 30 generally provided through computer aided design (CAD) software such as that developed by InCAM®Pro or PROFLEX®.

A computer numerically controlled (CNC) drill system, a laser or a tooling die set are all options available to precisely position holes (reference features 14) in the locations consistent with the CAD data set. As illustrated at FIG. 7, reference features (tooling holes) 14 are preferably formed in a substrate laminate panel 12 with an upper surface 55 and a lower surface 57 and combinations of longitudinally extending conducting and insulating layers at a repeating predefined distance along the substrate laminate panel.

Contemporaneous with the installation of the tooling hole reference features 14 an initial reference data set 30A is created based upon the initial locations of the reference feature tooling holes 14. While the original CAD data set 30 and the supplemental data set 30A should be nearly identical in terms of spatial arrangement of the reference features 14 it is possible that nominal variations on the location of the reference features 14 possibly induced by, for example, ambient temperature fluctuations, may exist and it is critical that the actual reference feature locations R1-RX be fully digitized for use in determining the demarcation (stitch) lines L1-LX. The spacing intervals between both adjacent and non-adjacent reference feature tooling holes R1-RX are captured as dataset 30A using a multi-dimensional vision system as detailed at Step B in FIG. 6. The actual spatial relationship among all the reference features 14 (relative to R1-RX) is now stored in the robust data set 30A.

Step C requires the utilization of an algorithmic methodology to digitally segment the substrate laminate panel 12 into multiple sections S1-SX, each with a subset of the total number of the reference feature tooling holes 14. The sections S1-SX are separated at digital demarcation lines L1-LX as best illustrated at FIG. 2. Precisely determining the location of the demarcation lines (stitch lines) L1-LX is critical for maintaining the integrity of the conductor traces as the laminate panel advances through the steps of the fabrication process. The digital demarcation (stitch) lines L1-LX, as noted above, traverse laterally across the laminate panel 12 dividing the laminate panel into a plurality of segments S1-SX. It is critical for the method and system 10 to maintain an awareness of each demarcation (stitch) line L1-LX that spans between each laterally opposed reference feature 14 pair.

Next, at Step D a photo-sensitive dry film or alternatively a wet film 60 (henceforth “film”) is applied across at least one of the upper surface 55 and the lower surface 57 of the substrate panel 14. Next at Step E, following the application of the film 60, the location of the reference feature tooling holes R1-RX are again visually acquired by the multi-dimensional machine vision system 32 creating yet another dataset 30A. Specifically, the locations of the tooling holes 14 relative to one another are visually acquired and digitally recorded to serve as reference points R1-RX in each of the multiple sections S1-SX of the substrate laminate panel 12. At Step F a measurement algorithm 38 is then applied to the newly acquired data 30A of the multiple sections S1-SX of the panel. The measurement algorithm 38 calculates the change in location, or displacement, of each of the reference features R1-RX relative to the initial two-dimensional data set 30 reference feature locations 14 and determines the precise location of each of the demarcation (stitch) lines L1-LX.

Step G requires the system 10 to access and execute a digital instruction dataset 66. This digital instruction dataset 66 contains instructions for precisely delivering a narrowly focused beam of electromagnetic energy 70 onto a photo-sensitive film 72. These instructional datasets 66 are specifically developed with software that is widely available to guide the beam of energy 70 on a particular substrate laminate panel 12. As illustrated at FIG. 8, the delivery of the beam of electromagnetic energy 70 to the photo-sensitive film 72 forms a pre-defined flexible circuit pattern 74.

Once the electromagnetic energy 70 is applied as directed by the dataset 66 instructions, the flexible circuit pattern 74 is complete. Next, at Step H the substrate laminate 12 is chemically washed to remove the uncured photo-sensitive film 72 resulting in the pre-defined film mask 76. Next, Step I requires at least one of (i) plating with copper (Step I), or (ii) chemically etching (Step J) to remove copper (Step K) from a plurality of electrical connections 78 on the pre-defined film mask 76. Following completion of Steps I or J and K, Step L requires removal of the remaining film mask 76 with a chemical solution wherein the exposed copper electrical connections are covered with a protective dielectric cover film.

Step M requires that the entire substrate laminate panel 12 with the protective dielectric cover film is placed into a single longitudinally extending static press, an exemplary static press is produced by French® Oil Mill Machinery Company, where heat and pressure are applied to permanently bond the copper traces and the protective dielectric cover film to one another. The static press imparts a pressure in the range of 200 to 400 psi onto the flexible circuit substrate materials with protective dielectric cover film while the temperature of the copper traces and protective dielectric cover film are raised into the range of 300° to 800° F. with a static press cycle time in the range of 3 to 5 hours.

Once the cycle time in the static press is completed, the multi-dimensional machine vision system 32 re-reacquires and digitizes the plurality of reference features R1-RX. The system 10 then applies the measurement algorithm 38 to the multi-dimensional vision system acquired digital data sets 30, 30A to correlate the position of each demarcation (stitch) lines L1-LX relative to the initial data set 30.

The objective of employing the measurement algorithm 38 of the multi-dimensional machine learning system 32 is to align with high precision the demarcation lines L1-LX separating the sections S1-SX to ensure trace 26 continuity along all sections S1-SX of the entire substrate laminate panel 12. Without proper alignment of the demarcation lines L1-LX identifying the terminus of each section S1-SX, the fully fabricated flexible circuit may lack electrical continuity effectively rendering the component non-functional.

The system 10 then transfers a positionally adjusted instruction set to an excising device, such as a laser or a computer numerically controlled (CNC) machine, where the positionally adjusted data set is used to detect, and correct, any fabrication and environmentally induced distortions within each of the panel sections S1-SX such as those shown in FIG. 2. Finally, the excising device longitudinally excises the substrate laminate panel 12 to produce a plurality of individual extended length flexible circuits that are generally greater than 36 inches in length, some of which may be 110 inches or more in length.

The disclosed system and method should not be construed as limiting in any way. Instead, the present disclosure is directed toward all novel and nonobvious features and aspects of the various disclosed method, alone and in various combinations and sub-combinations with one another. The disclosed method is not limited to any specific aspect or feature or combination thereof, nor do the disclosed method require that any one or more specific advantages be present, or problems be solved.

In view of the many possible embodiments to which the principles of the disclosed invention may be applied, it should be recognized that the illustrated embodiments are only examples of the disclosure and should not be taken as limiting the scope of the invention. Rather, the scope of the invention is defined by the following claims. We therefore claim as our invention all that comes within the scope of these claims.

The disclosure presented herein is believed to encompass at least one distinct invention with independent utility. While the at least one invention has been disclosed in exemplary forms, the specific embodiments thereof as described and illustrated herein are not to be considered in a limiting sense, as numerous variations are possible. Equivalent changes, modifications, and variations of the variety of embodiments, materials, compositions, and methods may be made within the scope of the present disclosure, achieving substantially similar results. The subject matter of the at least one invention includes all novel and non-obvious combinations and sub-combinations of the various elements, features, functions and/or properties disclosed herein and their equivalents.

Benefits, other advantages, and solutions to problems have been described herein regarding specific embodiments. However, the benefits, advantages, solutions to problems, and any element or combination of elements that may cause any benefits, advantage, or solution to occur or become more pronounced are not to be considered as critical, required, or essential features or elements of any or all the claims of at least one invention.

Many changes and modifications within the scope of the instant disclosure may be made without departing from the spirit thereof, and the one or more inventions described herein include all such modifications. Corresponding structures, materials, acts, and equivalents of all elements in the claims are intended to include any structure, material, or acts for performing the functions in combination with other claim elements as specifically recited. The scope of the one or more inventions should be determined by the appended claims and their legal equivalents, rather than by the examples set forth herein.

Benefits, other advantages, and solutions to problems have been described herein regarding specific embodiments. It should be noted that many alternative or additional functional relationships or physical connections may be present in a practical system. However, the benefits, advantages, solutions to problems, and any elements that may cause any benefit, advantage, or solution to occur or become more pronounced are not to be construed as critical, required, or essential features or elements of the inventions.

The scope of the inventions is accordingly to be limited by nothing other than the appended claims, in which reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C. Different cross-hatching is used throughout the figures to denote different parts but not necessarily to denote the same or different materials.

In the detailed description herein, references to “one embodiment,” “an embodiment,” “an example embodiment,” etc., indicate that the embodiment described may include a feature, structure, or characteristic, but every embodiment may not necessarily include the feature, structure, or characteristic. Moreover, such phrases are not necessarily referring to the same embodiment. Further, when a feature, structure, or characteristic is described relating to an embodiment, it is submitted that it is within the knowledge of one skilled in the art to affect such feature, structure, or characteristic relating to other embodiments whether or not explicitly described. After reading the description, it will be apparent to one skilled in the relevant art(s) how to implement the disclosure in alternative embodiments.

Furthermore, no element, component, or method step in the present disclosure is intended to be dedicated to the public regardless of whether the element, component, or method step is explicitly recited in the claims. No claim element herein is to be construed under the provisions of 35 U.S.C. § 112(f) unless the element is expressly recited using the phrase “means for.” As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The invention has been described above with reference to one or more preferred embodiments, it will be appreciated that various changes or modifications may be made without departing from the scope of the invention as defined in the appended claims.

We claim:

1. A method for aligning at least one conductor trace along an entire length of an extended length flexible circuit with longitudinally opposed first and second ends, the method comprising:
positioning a flexible laminate upon a surface;
utilizing a multi-dimensional machine vision system, scan the entire length of the flexible laminate including a plurality of reference points;
identifying in two-dimensions, with the multi-dimensional machine vision system, the location of each of the plurality of reference points;
digitally segmenting the flexible laminate by defining a plurality of digital stitch lines between each of an adjacent longitudinally extending segment;
following a subsequent flexible laminate fabrication step rescanning of the entire length of the flexible laminate including the plurality of reference points;
applying a measuring algorithm to determine the magnitude and direction of the displacement of each of the reference point locations relative to the plurality of original reference point locations;
positionally adjusting a subsequent fabrication process to account for the magnitude and direction of the displacement of the plurality of reference points to ensure continued alignment of the stitch lines between adjacent segments as well as alignment of the at least one conductor trace; and
repeating as necessary the steps of scanning, numerically identifying, digitally segmenting, measuring and adjusting following each flexible laminate fabrication process to ensure continued precise alignment of the stitch lines and the at least one conductor trace between adjacent segments.

2. The method of claim 1, wherein the reference points each comprise a center of a through hole proximate an edge of the flexible laminate.

3. The method of claim 1, wherein the flexible circuit comprises a dielectric substrate film, electrical conductors, a protective finish, and adhesives.

4. The method of claim 1, wherein the longitudinal length of each of the digital segments is in the range of 10 to 20 inches.

5. The method of claim 1, wherein each demarcation line laterally spans in the range of 10 to 20 inches.

6. The method of claim 1, wherein the thickness of the at least one trace is in the range of 0.0001 inches to 0.010 inches.

7. The method of claim 1, wherein the multi-dimensional machine vision system comprises a digital camera.

8. The method of claim 1, wherein the step of digitally segmenting comprises application of an alignment optimization algorithm.

9. The method of claim 1, wherein the flexible laminate fabrication process step comprises large format press operations.

10. The method of claim 9, wherein large format press operations comprise presses of greater than 30 inches.

11. A system for aligning at least one conductor trace along an entire length of an extended length flexible circuit with longitudinally opposed first and second ends, the system comprising:
a multi-dimensional machine vision system, the multi-dimensional machine vision system operable to scan the entire length of the flexible laminate including locating a plurality of reference points and stitch lines in multiple dimensions;
an alignment optimization algorithm to digitally stitch together at the stitch lines a plurality of discrete segments of the extended length flexible circuit captured by the multi-dimensional machine vision system;
a measurement algorithm to determine the magnitude and direction of the displacement of each of the reference point locations relative to the plurality of original reference point locations subsequent to another fabrication process step; and
a fabrication process controller operable to positionally adjust a subsequent fabrication process to account for the magnitude and direction of the displacement of the plurality of reference points to ensure continued alignment of the multiple discrete segments as well as alignment of the at least one conductor trace.

12. A method for fabricating an extended length flexible circuit with longitudinally opposed first and second ends, the method comprising:
installing tooling features consistent with an initial data set provided by computer aided design data, the tooling holes formed in a sized substrate laminate panel with an upper and a lower surface and combinations of longitudinally extending conducting and insulating layers at a repeating predefined distance along the substrate laminate panel;
contemporaneous with the installation of the tooling features, creating an initial reference data set based upon the initial locations of the tooling features, wherein spacing intervals between both adjacent and non-adjacent holes are captured and the substrate laminate panel is digitally segmented into multiple sections each with a subset of a total number of tooling features;
applying a photo-sensitive film across at least one of the upper surface and the lower surface;
visually acquiring the location of the tooling features relative to one another to serve as reference points in each of the multiple sections of the substrate laminate panel;
digitally recording the visually acquired location of the tooling features;
utilizing a measurement algorithm on the visually acquired digital data of the multiple sections of the panel to determine any positional changes in the location of the tooling features relative to the initial two-dimensional data set following application of the photo-sensitive film;
by referencing a stored digital dataset, directionally directing a beam of electromagnetic energy of one or more specific wavelengths to the applied photo-sensitive film to form a pre-defined flexible circuit pattern;
chemically washing the sized substrate laminate to remove the uncured photo-sensitive film resulting in a pre-defined film mask;
performing at least one of (i) plating with copper, or (ii) chemically etching to remove copper from a plurality of electrical connections on the pre-defined film mask;
removing the remaining film mask with a chemical solution;
covering with a protective dielectric cover film, the exposed copper electrical connections;
placing the entire substrate laminate panel with protective dielectric cover film into a single static press where heat and pressure are applied to permanently bond the substrate material and the protective dielectric cover film to one another;
visually re-acquiring the tooling features;
digitizing the re-acquired tooling features;
re-scaling the visually acquired data of the multiple sections to correlate the dimensional changes in each of the sections relative to the initial data set;
transferring a re-scaled data set to an excising device;
using the re-scaled data set to detect, and correct, any fabrication and environmentally induced distortion within each of the sections; and
longitudinally excising the substrate laminate panel to produce a plurality of individual extended length flexible circuits.

13. The method of claim 12, wherein the extended length flexible circuit is at least 36 inches from the first end to the second end.

14. The method of claim 13, wherein the extended length flexible circuit is at least 50 inches from the first end to the second end.

15. The method of claim 12, wherein the step of installing tooling features comprises using at least one of a laser, mechanical drilling and tooling die set.

16. The method of claim 12, wherein at least one of a charged coupled device (CCD) camera or a video camera digitally captures the initial location of the tooling features.

17. The method of claim 12, wherein the static press imparts a pressure onto the flexible circuit substrate materials with protective dielectric cover film in the range of about 200 to 400 psi.

18. The method of claim 12, wherein the static press increases the temperature of the substrate with protective dielectric cover film into the range of about 300° to 800° F.

19. The method of claim 12, wherein the cycle time of the static press is in the range of about 3 to 5 hours.

20. The method of claim 12, wherein the original location of the tooling holes is determined by a computer aided design data set.

21. The method of claim 12, wherein the excising device comprises at least one of a laser, a water jet, a numerically controlled knife or a numerically controlled routing machine.

22. The method of claim 12, wherein the step of referencing a stored digital dataset and directionally directing a beam of electromagnetic energy of one or more specific wavelengths to the applied photo-sensitive film to form a pre-defined flexible circuit pattern is performed in a single pass.
